(19) United States
(12) Patent Application Publication
(10) Pub. No.: US 2019/0100663 A1
(43) Pub. Date: Apr. 4, 2019

(54) ANISOTROPIC CONDUCTIVE FILM AND METHOD FOR MANUFACTURING ANISOTROPIC CONDUCTIVE FILM

(71) Applicant: SHIN-ETSU CHEMICAL CO., LTD., Tokyo (JP)

(72) Inventors: Hiroyuki IGUCHI, Annaka-shi (JP); Toshio SHIOBARA, Annaka-shi (JP); Tsutomu KASHIWAGI, Annaka-shi (JP)

(73) Assignee: SHIN-ETSU CHEMICAL CO., LTD., Tokyo (JP)

(21) Appl. No.: 16/126,223

(22) Filed: Sep. 10, 2018

(30) Foreign Application Priority Data
Oct. 3, 2017 (JP) 2017-193767
Oct. 4, 2017 (JP) 2017-194315

(51) Int. Cl. C09D 5/24; H01L 25/075; H01L 23/00; C08G 77/20; C08G 77/12; C09D 183/04; B05D 1/06; B05D 7/00

(52) U.S. Cl. CPC C09D 5/24; H01L 25/0753; H01L 24/29; C08G 77/20; C08G 77/12; H01L 2224/29291; B05D 1/06; B05D 7/586; H01L 2924/12041; H01L 2224/29499; C09D 183/04

(57) ABSTRACT

The present invention is an anisotropic conductive film including: a peelable substrate, a base layer containing an insulating resin on the peelable substrate, bumps of electroconductive nanoparticle assemblies disposed on the base layer at intervals of 1 μm to 100 μm, and a coating layer containing an insulating resin formed on the base layer so as to coat the bumps, wherein the peelable substrate is peelable to the base layer. This provides an anisotropic conductive film for connecting circuit electrodes having fine patterns.

### TECHNICAL FIELD

The present invention relates to an anisotropic conductive film and a method for manufacturing an anisotropic conductive film.

### BACKGROUND ART

In recent years, Anisotropic Conductive Films (ACF) have been used instead of solder in connecting a flat panel display such as a Liquid Crystal Display (LCD) or electronic parts in a precision instrument with each other. The anisotropic conductive film is mainly composed of an insulating resin containing electroconductive particles, and is disposed between circuit electrodes to bring contact bonding by pressing and heating, thereby making it possible to electrically connect the circuits.

Patent Literature 1 discloses an anisotropic conductive film produced by applying a mixture of a polyvinyl butyral resin and an epoxy resin that contains particles of tin-lead solder having an average particle size of 10 μm and a maximum particle size of 15 μm. In Patent Literature 2, nickel particles in an average particle size of 2 μm are mixed with a phenoxy resin to produce an anisotropic conductive film using a coating equipment. Patent Literature 3 discloses an anisotropic conductive film produced by mixing silver-plated resin particles in an average particle size of 20 μm and an insulating resin, followed by coating. In Patent Literature 4, an anisotropic conductive film is produced by printing an epoxy resin that contains silver powders in an average particle size of 5 to 10 μm onto an epoxy resin layer, followed by coating of epoxy resin thereon, and repeating printing of the epoxy resin that contain silver powders and coating of the epoxy resin.

In any of the films described in the foregoing Patent Literatures, however, micro particles are mixed with a resin for application, thereby making the particles aggregate with each other. Accordingly, it is difficult to keep the electroconductive area in a size of 100 μm or less while keeping the insulation in the planar direction of the film. On the other hand, when the concentration of particles is reduced to prevent aggregation of the particles, it becomes difficult to keep the electric conductivity in the cross sectional direction of the film. Accordingly, it is impossible to electrically connect circuit electrodes having fine patterns.

Patent Literatures 5 and 6 report an anisotropic conductive film in which electroconductive particles are disposed in a lattice form with the intervals between the adjacent dispositions having width and narrowness at least in one direction. In this method, an electrode at one portion is electrically connected by a plurality of micro electroconductive particles, and the distances between the bumps are not constant. Accordingly, it is not suitable for connecting circuit electrodes having fine patterns.

In Patent Literature 7, an anisotropic conductive film is produced by introducing a porous plate into a vessel that contains electroconductive particles, with the porous plate having pores smaller than the particle size of the electroconductive particles, followed by reducing the pressure of the side being separated by the porous plate and opposite to the side that contains the electroconductive particles to capture the electroconductive particles on the porous plate. In this method, however, the particles are inevitably large since it is necessary to prepare a porous plate that has pores smaller than the particle size, and it is also necessary to reduce the pressure of the side opposite to the side that contains the electroconductive particles, thereby increasing the steps to increase the cost extremely. As described above, it has been difficult to dispose electroconductive particles regularly at low cost.

### CITATION LIST

### Patent Literature

Patent Literature 1: Japanese Unexamined Patent Application Publication No. H5-154857

Patent Literature 2: Japanese Unexamined Patent Application Publication No. 2008-112713

Patent Literature 3: Japanese Unexamined Patent Application Publication No. 2015-147832

Patent Literature 4: Japanese Unexamined Patent Application Publication No. 2003-151713

Patent Literature 5: Japanese Unexamined Patent Application Publication No. 2016-085931

Patent Literature 6: International Patent Laid-Open Publication No. WO 2016/104463

Patent Literature 7: Japanese Unexamined Patent Application Publication No. 2005-209454

### SUMMARY OF THE INVENTION

### Technical Problem

The present invention has been accomplished in view of the foregoing problems, and an object thereof is to provide an anisotropic conductive film for connecting circuit electrodes having fine patterns. Additionally, another object of the present invention is to provide a method for manufacturing an anisotropic conductive film in which bumps with a designated average diameter that contain electroconductive nanoparticles are disposed in designated intervals.

### Solution to Problem

To solve the above problems, the present invention provides an anisotropic conductive film comprising:

a peelable substrate,

a base layer containing an insulating resin on the peelable substrate,

bumps of electroconductive nanoparticle assemblies disposed on the base layer at intervals of 1 μm to 100 μm, and

a coating layer containing an insulating resin formed on the base layer so as to coat the bumps,

wherein the peelable substrate is peelable to the base layer.

The anisotropic conductive film like this makes it possible to connect circuit electrodes having fine patterns.

It is preferable that the bumps have an average diameter of 1 μm to 100 μm.

When the bumps have such an average diameter, it becomes possible to connect circuit electrodes having fine patterns more securely.

It is preferable that the electroconductive nanoparticle assemblies be each an assembly composed of electroconductive nanoparticles having primary particle sizes of 1 nm to 500 nm.

With the electroconductive nanoparticle assembly like this, it is possible to form bumps in desired sizes easily.

The base layer preferably has a thickness that is 1% to 100% of the average diameter of the bumps.

With such a thickness, the base layer prevents the electroconductive nanoparticles from being repelled by the peelable substrate, thereby allowing the bumps to be disposed easily.

The coating layer preferably has a thickness that is 101% to 500% of the average diameter of the bumps.

With such a thickness, the coating layer prevents the electroconductive nanoparticle assemblies from being exposed to the surface to avoid degradation of the electroconductive nanoparticles. When a circuit electrode is pressed thereto, the electrode and the bumps are allowed to be in contact with each other more securely to form electrical connection.

It is preferable that at least either of the base layer and the coating layer contain a silicone resin as the insulating resin, containing the following components (A), (B), and (C):

(A) a silicone resin shown by the following average formula (1):

R¹ₐR²_{b}R³_{c}(OX)_{d}SiO_{(4-a-b-c-d)/2} (1)

wherein R¹ represents a monovalent aromatic hydrocarbon group having 6 to 12 carbon atoms; R² represents a saturated hydrocarbon group having 1 to 6 carbon atoms; R³ represents an alkenyl group having 2 to 6 carbon atoms; X represents a monovalent hydrocarbon group having 1 to 6 carbon atoms or a hydrogen atom; and “a”, “b”, “c”, and “d” are each number of a≥0, b>0, c>0, and d≥0, satisfying a+b+c+d=1 to 2; provided that at least two alkenyl groups are contained in one molecule;

(B) a silicone resin shown by the following average formula (2):

R¹ₑR²_{f}H_{g}(OX)ₕSiO_{(4-e-f-g-h)/2} (2)

wherein R¹, R², and X represent the same meanings as R¹, R², and X described above; “e”, “f”, “g”, and “h” are each number of e≥0, f>0, g>0, and h≥0, satisfying e+f+g+h=1 to 2; provided that at least two silicon atom-bonded hydrogen atoms are contained in one molecule; and

(C) a hydrosilylation catalyst.

The anisotropic conductive film like this is really excellent in heat resistance and light resistance.

The silicone resin is preferably solid at 25° C.

The silicone resin like this allows the anisotropic conductive film to be really excellent in workability in production.

The present invention also provides a method for manufacturing an anisotropic conductive film, comprising the steps of:

(1) performing coating of a composition containing an insulating resin onto a peelable substrate to form a base layer;

(2) applying voltage to a dispersion of electroconductive nanoparticles to apply the dispersion of electroconductive nanoparticles onto the base layer through a nozzle by electrostatic force, whereby disposing bumps of electroconductive nanoparticle assemblies on the base layer at intervals of 1 μm to 100 μm; and

(3) performing coating of a composition containing an insulating resin so as to coat surfaces of the bumps to form a coating layer on the base layer.

The method for manufacturing an anisotropic conductive film like this makes it possible to easily manufacture the anisotropic conductive film comprising: a peelable substrate, a base layer containing an insulating resin on the peelable substrate, bumps of electroconductive nanoparticle assemblies disposed on the base layer at intervals of 1 μm to 100 μm, and a coating layer containing an insulating resin formed on the base layer so as to coat the bumps, wherein the peelable substrate is peelable to the base layer.

It is preferable to comprise the steps of:

(1)′ curing the base layer between the step (1) and the step (2); and/or

(3)′ curing the coating layer after the step (3).

The method for manufacturing an anisotropic conductive film makes it possible to easily manufacture an anisotropic conductive film that is really excellent in heat resistance and light resistance.

The present invention also provides a method for manufacturing an anisotropic conductive film, comprising the steps of:

(1) applying voltage to a dispersion of electroconductive nanoparticles to apply the dispersion of electroconductive nanoparticles onto a peelable substrate through a nozzle by electrostatic force, whereby disposing bumps having an average diameter of 1 μm or more and less than 100 μm on the peelable substrate at intervals of 1 μm or more and 100 μm or less;

(2) performing coating of a composition containing an insulating resin so as to have a thickness of 10 μm or more and 100 μm or less to coat surfaces of the bumps, whereby forming an insulating resin layer; and

(3) curing the insulating resin layer, followed by peeling the peelable substrate to obtain a film.

The method for manufacturing an anisotropic conductive film like this makes it possible to easily manufacture an anisotropic conductive film in which bumps with an average diameter of 1 μm or more and less than 100 μm containing electroconductive nanoparticles are disposed at intervals of 1 μm or more and 100 μm or less.

The bumps preferably have diameters that are 10% or more and 90% or less of the thickness of the film.

When the bumps have such diameters, it becomes possible to connect circuit electrodes and electroconductive nanoparticles more securely.

The insulating resin layer is preferably cured by any of heat-curing, photo-curing, and moisture-curing.

These types of curing allow the insulating resin layer to be cured more efficiently.

The dispersion of electroconductive nanoparticles preferably has a nanoparticle concentration of 0.001 mass % or more and 30 mass % or less.

When the dispersion of electroconductive nanoparticles has such a concentration of nanoparticles, it becomes possible to form desirable bumps more securely.

The insulating resin is preferably a silicone resin.

The insulating resin like this makes it possible to obtain a film that is excellent in heat resistance and light resistance.

The insulating resin is preferably solid at 25° C.

The insulating resin like this enables the method to manufacture an anisotropic conductive film that is really excellent in workability in production.

### Advantageous Effects of Invention

As described above, the inventive anisotropic conductive film makes it possible to electrically connect circuit electrodes having extremely fine patterns to achieve miniaturization, thickness reduction, and weight reduction of electronic equipment. In addition, the inventive method for manufacturing an anisotropic conductive film makes it possible to easily manufacture an anisotropic conductive film in which bumps with an average diameter of 1 μm or more and less than 100 μm containing electroconductive nanoparticles are disposed at intervals of 1 μm or more and 100 μm or less. Moreover, the inventive method for manufacturing an anisotropic conductive film makes it possible to manufacture an anisotropic conductive film that has electroconductive areas in a size of several μm to several tens μm disposed at regular intervals. Accordingly, it is possible to electrically connect circuit electrodes having extremely fine patterns to achieve miniaturization, thickness reduction, and weight reduction of electronic equipment.

### BRIEF DESCRIPTION OF DRAWINGS

FIG. 1 is a schematic view of the cross section in which a base layer has been formed on a peelable substrate in Example 1;

FIG. 2 is a schematic view of the cross section in which bumps of electroconductive nanoparticle assemblies has been formed on a base layer in Example 1;

FIG. 3 is a schematic view of the cross section in which a coating layer has been formed after forming the bumps in Example 1;

FIG. 4 is an example of a photograph of an external view of a base layer after being applied with silver nanoparticles in Example 1;

FIG. 5 is an example of a photograph of an external view of a base layer after being applied with silver nanoparticles in Example 2;

FIG. 6 is an example of a photograph of an external view of a base layer after being applied with silver nanoparticles in Example 3;

FIG. 7 is an example of a photograph of an external view of a base layer after being applied with silver nanoparticles in Example 4;

FIG. 8 is an example of a photograph of an external view of a base layer after being applied with silver nanoparticles in Example 5;

FIG. 9 is a schematic view of the cross section of a film onto which circuit electrodes (micro LEDs) have been pressed in energization test in Examples and Comparative Examples;

FIG. 10 is an example of a photograph of an external view of an ETFE film after being applied with silver nanoparticles in Preparation Example 5;

FIG. 11 is an example of a photograph of an external view of an ETFE film after being applied with silver nanoparticles in Preparation Example 6;

FIG. 12 is an example of a photograph of an external view of an ETFE film after being applied with silver nanoparticles in Preparation Example 7;

FIG. 13 is an example of a photograph of an external view of an ETFE film after being applied with silver nanoparticles in Preparation Example 8;

FIG. 14 is an example of a photograph of an external view of an ETFE film after being applied with silver nanoparticles in Comparative Preparation Example 3;

FIG. 15 is an example of a photograph of an external view of an ETFE film after being applied with silver nanoparticles in Comparative Preparation Example 4;

FIG. 16 is an example of a photograph of an external view of an ETFE film after being applied with silver nanoparticles in Comparative Preparation Example 5;

FIG. 17 is a schematic view of the cross section of a film produced in Example 6;

FIG. 18 is a schematic view of the cross section of a film onto which circuit electrodes (micro LEDs) have been pressed in energization test in Examples.

### DESCRIPTION OF EMBODIMENTS

As described above, it has been desired to develop an anisotropic conductive film for connecting circuit electrodes having fine patterns, together with a method for manufacturing an anisotropic conductive film in which bumps with an average diameter of 1 μm or more and less than 100 μm containing electroconductive nanoparticles are disposed at intervals of 1 μm or more and 100 μm or less.

The inventors have diligently investigated to achieve the above objects to find that circuit electrodes with fine patterns are electrically connected successfully by using an anisotropic conductive film comprising: a peelable substrate, a base layer containing an insulating resin on the peelable substrate, bumps of electroconductive nanoparticle assemblies disposed on the base layer at intervals of 1 μm to 100 μm, and a coating layer containing an insulating resin formed on the base layer so as to coat the bumps, wherein the peelable substrate is peelable to the base layer; and circuit electrodes with fine patterns are also electrically connected successfully by applying voltage to a dispersion of electroconductive nanoparticles to apply the dispersion of electroconductive nanoparticles through a nozzle by electrostatic force, whereby disposing bumps having an average diameter of 1 μm or more and less than 100 μm at intervals of 1 μm or more and 100 μm or less; thereby bringing the present invention to completion.

That is, the present invention is an anisotropic conductive film comprising:

a peelable substrate,

a base layer containing an insulating resin on the peelable substrate,

bumps of electroconductive nanoparticle assemblies disposed on the base layer at intervals of 1 μm to 100 μm, and

a coating layer containing an insulating resin formed on the base layer so as to coat the bumps,

wherein the peelable substrate is peelable to the base layer.

Hereinafter, the inventive anisotropic conductive film will be specifically described, but the present invention is not limited thereto.

### [Peelable Substrate]

The peelable substrate used for the present invention is not particularly limited as long as the substrate is peelable after curing or semi-curing a base layer and a coating layer, which will be described below, and the illustrative examples thereof include fluorine films and PET films treated with a releasing agent. The thickness of the peelable substrate is not particularly limited, and can be selected in accordance with the object, but is preferably 10 μm to 1,000 μm.

Herein, “semi-curing” means being in a state so called “B stage” and, when the insulating resin contained in the base layer to be given later is a thermosetting resin, refers to an intermediate state in which the resin is not fully cured although the resin surface has lost tackiness after heating from the uncured state.

### [Base Layer]

The base layer contains an insulating resin and is used for disposing bumps of electroconductive nanoparticle assemblies, which will be described later. In some cases, without the base layer, the peelable substrate repels the electroconductive nanoparticles to fail to form desirable bumps.

The insulating resin contained in the base layer is not particularly limited as long as it is peelable from the peelable substrate, and illustrative examples thereof include thermoplastic resins such as an acrylic resin, a polyester resin, a polyethylene resin, a cellulose resin, a styrene resin, a polyamide resin, a polyimide resin, and a melamine resin; and thermosetting resins such as a silicone resin, an epoxy resin, a silicone-epoxy resin, a phenol resin, and a perfluoropolyether resin. In view of the heat resistance and light resistance, a silicone resin and an epoxy resin are preferable, and a silicone resin is more preferable. Illustrative examples of the silicone resin include UV-curing, heat-curing, and moisture-curing silicone resins.

The base layer preferably has a thickness that is 1% to 100%, more preferably 5% to 80%, still more preferably 10% to 50% of the average diameter of the bumps of electroconductive nanoparticle assemblies, which will be described later. When the base layer has a thickness in such a range, the peelable substrate does not repel the electroconductive nanoparticles, thereby allowing the bumps to be easily disposed.

### [Electroconductive Nanoparticle]

The electroconductive nanoparticle used for the present invention is not particularly limited, and can be selected appropriately in accordance with the object. Illustrative examples thereof include metal particles, electroconductive polymer particles, and metal-coated particles.

Illustrative examples of the metal particles include metal simple substances such as gold, silver, copper, palladium, aluminum, nickel, iron, titanium, manganese, zinc, tungsten, platinum, lead, and tin; and alloys such as solder, steel, and stainless steel. They may be used alone or in combination of two or more kinds. Illustrative examples of the electroconductive polymer particles include carbon, polyacetylene nanoparticles, and polypyrrole nanoparticles. Illustrative examples of the metal-coated particles include resin particles, the surfaces of which are coated with metal as well as inorganic particles such as glasses or ceramics, the surfaces of which are coated with metal. The method for coating the surface with metal is not particularly limited, and illustrative examples thereof include an electroless plating method and a sputtering method.

The electroconductive nanoparticle described above is usable as long as it has electric conductivity when it is electrically connected to a circuit electrode. For example, even a particle having a surface treated with insulating coating are included in the electroconductive nanoparticles if the particle changes its shape to expose the metal particle when it is electrically connected.

The average particle size of the electroconductive nanoparticles described above is not particularly limited, and is preferably 1 nm to 500 nm in order to form bumps of electroconductive nanoparticle assemblies with the average diameter of 1 μm to 100 μm, which will be described later. The average particle size is more preferably 5 nm to 400 nm, still more preferably 10 nm to 300 nm. In this range, it becomes easy to form bumps with the average diameter of 1 μm to 100 μm when the dispersion of the electroconductive nanoparticles is applied as described later. Incidentally, the average particle size of the nanoparticles can be an average value of maximum diameters of 100 particles measured through a transmission electron microscope, for example.

### [Bump of Electroconductive Nanoparticle Assembly]

The bumps of electroconductive nanoparticle assemblies preferably have an average diameter of 1 μm to 100 μm, more preferably 2 μm to 50 μm, still more preferably 3 μm to 20 μm. The above bumps are disposed at intervals of 1 μm to 100 μm, preferably 2 μm to 50 μm, more preferably 3 μm to 20 μm. Incidentally, in the present invention, the average diameter of bumps described above can be an average value of maximum diameters of 100 bumps observed through an optical microscope, for example. The interval of bumps may be an average value of arbitrary 99 points of intervals between two adjacent bumps observed through an optical microscope, for example.

The method for applying the electroconductive nanoparticles onto a base layer is not particularly limited. It is preferable, however, to apply the dispersion of electroconductive nanoparticles by electrostatic force in order to dispose the above bumps at intervals of 1 μm to 100 μm. A dispersion of electroconductive nanoparticles is sucked through a nozzle, and voltage is applied to the dispersion of electroconductive nanoparticles to add electric charges to the dispersion of electroconductive nanoparticles, making the electroconductive nanoparticle assemblies repel with each other when applied, which is used in this method.

### [Coating Layer]

After the bumps are disposed onto the base layer, a coating layer containing an insulating resin is formed so as to coat the bumps. The insulating resin contained in the coating layer is not particularly limited, and the same ones as the ones described in the above base layer can be exemplified. Illustrative examples thereof include thermoplastic resins such as an acrylic resin, a polyester resin, a polyethylene resin, a cellulose resin, a styrene resin, a polyamide resin, a polyimide resin, and a melamine resin; and thermosetting resins such as a silicone resin, an epoxy resin, a silicone-epoxy resin, a phenol resin, and a perfluoropolyether resin. In view of the heat resistance and light resistance, a silicone resin and an epoxy resin are preferable, and a silicone resin is more preferable. Illustrative examples of the silicone resin include UV-curing, heat-curing, and moisture-curing silicone resins. It is to be noted that the kind of the insulating resin used for the coating layer and the insulating resin contained in the base layer may be the same or different.

The coating layer preferably has a thickness that is 101% to 500%, more preferably 101% to 300% of the average diameter of the bumps. In this range, the electroconductive nanoparticle assemblies are prevented from being exposed to the surface, and avoided from degradation thereby. When a circuit electrode is pressed thereto, the electrode and the bumps are allowed to be in contact with each other more securely to form electrical connection.

After forming the coating layer, a peelable film may be bonded onto the coating layer. Illustrative examples of the peelable film include PET films coated with a fluorine resin, PET films coated with a silicone resin, and fluorine resin films.

As described above, the inventive anisotropic conductive film makes it possible to connect circuit electrodes having fine patterns.

The present invention also provides a method for manufacturing an anisotropic conductive film, comprising the steps of:

(1) performing coating of a composition containing an insulating resin onto a peelable substrate to form a base layer;

(2) applying voltage to a dispersion of electroconductive nanoparticles to apply the dispersion of electroconductive nanoparticles onto the base layer through a nozzle by electrostatic force, whereby disposing bumps of electroconductive nanoparticle assemblies on the base layer at intervals of 1 μm to 100 μm; and

(3) performing coating of a composition containing an insulating resin so as to coat surfaces of the bumps to form a coating layer on the base layer.

Hereinafter, the inventive method for manufacturing an anisotropic conductive film will be specifically described, but the present invention is not limited thereto.

### [Step (1)]

The step (1) is a step of coating a composition containing an insulating resin onto a peelable substrate to form a base layer.

The composition that contains the insulating resin may contain any components other than the insulating resin contained in the base layer, including a solvent, for example.

The base layer can be formed by a previously known method, and a film coater or a hot press machine can be used, for example. Illustrative examples of the film coater include a direct gravure coater, a chamber doctor coater, an offset gravure coater, a roll kiss coater, a reverse kiss coater, a bar coater, a die coater, a reverse roll coater, a slot die, an air doctor coater, a normal rotation roll coater, a blade coater, a knife coater, an impregnation coater, an MB coater, and an MB reverse coater. The coating may be performed by spraying through a nozzle using the same apparatus as the ones for applying the dispersion of electroconductive nanoparticles as described later.

### [Step (1)′]

The step (1)′ is a step of curing the base layer. When a thermoplastic resin is used for the base layer, the step (1)′ is not necessary. The method of curing is not particularly limited, and the curing can be performed by a method such as UV-curing, heat-curing, and moisture-curing.

### [Step (2)]

The step (2) is a step of applying voltage to the dispersion of electroconductive nanoparticles to apply the dispersion of electroconductive nanoparticles onto the base layer through a nozzle by electrostatic force, whereby disposing bumps of electroconductive nanoparticle assemblies on the base layer at intervals of 1 μm to 100 μm.

### [Dispersion of Electroconductive Nanoparticles]

For the dispersion of electroconductive nanoparticles, it is possible to use electroconductive nanoparticles described above. The dispersive medium of the dispersion of the electroconductive nanoparticles is not particularly limited, and can be appropriately selected in accordance with volatility, polarity, or wettability to the base layer containing a curable silicone resin, for example. Illustrative examples thereof include alcohols such as methanol, ethanol, 1-propanol, isopropyl alcohol, 1-butanol, and terpineol; ketones such as acetone, methyl ethyl ketone, and methyl isobutyl ketone; esters such as ethyl acetate and propylene glycol-1-monomethyl ether-1-acetate; amides such as N,N-dimethylformamide and N,N-dimethylacetamide; ethers such as diethyl ether, dibutyl ether, and tetrahydrofuran; aromatic hydrocarbons such as benzene, toluene, and xylene; aliphatic hydrocarbons such as hexane and heptane; halogenated hydrocarbons such as methylene chloride and chloroform; carboxylic acids such as formic acid and acetic acid; acetonitrile; dimethyl sulfoxide; and water. Among them, the use of methanol, ethanol, terpineol, and water are preferable. They may be used alone or in combination of two or more kinds. The dispersion of electroconductive nanoparticles preferably has a nanoparticle concentration of 10 mass % to 80 mass %, more preferably 20 mass % to 70 mass %, still more preferably 30 mass % to 60 mass %.

The dispersion of electroconductive nanoparticles may further contain a resin component as a binder. Illustrative examples of the resin component include a polyester resin, a polyethylene resin, a cellulose resin, an acrylic resin, a styrene resin, a polyamide resin, a melamine resin, a phenol resin, an epoxy resin, and a silicone resin. They may be used alone or in combination of two or more kinds. When these resin components are contained as a binder, it is preferable to use the same resin as in the base layer or the coating layer in view of fixing or adhering the nanoparticles.

When the dispersion of electroconductive nanoparticles contains a resin, the viscosity is not particularly limited, but is preferably 10,000 mPa·s or less, more preferably 5,000 mPa·s or less, still more preferably 1,000 mPa·s or less in order to apply it through a nozzle by electrostatic force. Incidentally, the viscosity in this description refers to a value measured at 25° C. with a rotational viscometer by the method described in JIS K 7117-1:1999.

### [Application]

An apparatus used for applying the dispersion of electroconductive nanoparticles is the one that applies the dispersion of electroconductive nanoparticles by electrostatic force. The dispersion of electroconductive nanoparticles is applied by being sucked through a nozzle and applying voltage to the dispersion of electroconductive nanoparticles. The usable apparatuses are exemplified in JP 2009-016490A and JP 2014-120490A.

The shape of the nozzle is not particularly limited, but is preferably a circular shape in order to apply voltage uniformly to the dispersion of electroconductive nanoparticles.

The diameter of the nozzle is not particularly limited, but is preferably 1 μm to 300 μm, more preferably 3 μm to 200 μm, still more preferably 5 μm to 100 μm in order to form bumps with an average diameter of 1 μm or more and less than 100 μm. In this range, it is easy to apply bumps with an average diameter of 1 μm to 100 μm.

The voltage applied thereto is not particularly limited, but is preferably 1,000 V to 10,000 V, more preferably 1,500 V to 8,000 V, still more preferably 2,000 V to 5,000 V. The distance between the tip of the nozzle and the base layer is, for example, 10 μm to 3,000 μm, preferably 20 μm to 2,000 μm.

### [Step (3)]

The step (3) is a step of coating a composition containing an insulating resin so as to coat surfaces of the bumps to form a coating layer on the base layer.

The composition that contains the insulating resin may contain any components other than the insulating resin contained in the coating layer, including a solvent, for example.

The coating layer can be formed by a previously known method, and a film coater or a hot press machine can be used, for example. Illustrative examples of the film coater include a direct gravure coater, a chamber doctor coater, an offset gravure coater, a roll kiss coater, a reverse kiss coater, a bar coater, a die coater, a reverse roll coater, a slot die, an air doctor coater, a normal rotation roll coater, a blade coater, a knife coater, an impregnation coater, an MB coater, and an MB reverse coater. The coating may be performed by spraying through a nozzle using the same apparatus as the ones for applying the dispersion of electroconductive nanoparticles as described above.

### [Step (3)′]

The step (3)′ is a step of curing the coating layer. When a thermoplastic resin is used for the coating layer, the step (3)′ is not necessary. The method of curing is not particularly limited, and the curing can be performed by a method such as UV-curing, heat-curing, and moisture-curing.

As described above, the inventive method for manufacturing an anisotropic conductive film makes it possible to easily manufacture the anisotropic conductive film comprising: a peelable substrate, a base layer containing an insulating resin on the peelable substrate, bumps of electroconductive nanoparticle assemblies disposed on the base layer at intervals of 1 μm to 100 μm, and a coating layer containing an insulating resin formed on the base layer so as to coat the bumps, wherein the peelable substrate is peelable to the base layer.

The present invention further provides a method for manufacturing an anisotropic conductive film, comprising the steps of:

(1) applying voltage to a dispersion of electroconductive nanoparticles to apply the dispersion of electroconductive nanoparticles onto a peelable substrate through a nozzle by electrostatic force, whereby disposing bumps having an average diameter of 1 μm or more and less than 100 μm on the peelable substrate at intervals of 1 μm or more and 100 μm or less;

(2) performing coating of a composition containing an insulating resin so as to have a thickness of 10 μm or more and 100 μm or less to coat surfaces of the bumps, whereby forming an insulating resin layer; and

(3) curing the insulating resin layer, followed by peeling the peelable substrate to obtain a film.

Hereinafter, the inventive method for manufacturing an anisotropic conductive film will be specifically described, but the present invention is not limited thereto.

### [Step (1)]

The step (1) is a step of applying voltage to a dispersion of electroconductive nanoparticles to apply the dispersion of electroconductive nanoparticles onto a peelable substrate through a nozzle by electrostatic force, whereby disposing bumps having an average diameter of 1 μm or more and less than 100 μm on the peelable substrate at intervals of 1 μm or more and 100 μm or less.

### [Peelable Substrate]

The peelable substrate used for the present invention is not particularly limited as long as the substrate is peelable after curing the insulating resin layer, which will be described below, for example, including silicone films, fluorine films, and PET films treated with a releasing agent. The thickness of the peelable substrate is not particularly limited, and can be selected in accordance with the object, but is preferably 10 μm or more and 1,000 μm or less.

### [Dispersion of Electroconductive Nanoparticles]

The electroconductive nanoparticle used for the present invention is not particularly limited, and can be selected appropriately in accordance with the object. Illustrative examples thereof include metal particles, electroconductive polymer particles, and metal-coated particles.

Illustrative examples of the metal particles include metal simple substances such as gold, silver, copper, palladium, aluminum, nickel, iron, titanium, manganese, zinc, tungsten, platinum, lead, and tin; and alloys such as solder, steel, and stainless steel. They may be used alone or in combination of two or more kinds. Illustrative examples of the electroconductive polymer particles include carbon, polyacetylene nanoparticles, and polypyrrole nanoparticles. Illustrative examples of the metal-coated particles include resin particles, the surfaces of which are coated with metal as well as inorganic particles such as glasses or ceramics, the surfaces of which are coated with metal. The method for coating the surface with metal is not particularly limited, and illustrative examples thereof include an electroless plating method and a sputtering method.

The electroconductive nanoparticle described above is usable as long as it has electric conductivity on the occasion of electrical connection to a circuit electrode. For example, even particles having surfaces treated with insulating coating correspond to the electroconductive nanoparticles if the particles change the shapes to expose the metal particles in the electrical connection.

The average particle size of the electroconductive nanoparticles described above is not particularly limited, but is preferably 1 μm or less in order to form bumps with the average diameter of 1 μm or more and less than 100 μm, which will be described later. The average particle size is more preferably 1 nm or more and 500 nm or less, still more preferably 1 nm or more and 300 nm or less. In this range, it becomes easy to form bumps with the average diameter of 1 μm or more and less than 100 μm when the dispersion of the electroconductive nanoparticles is applied. Incidentally, the average particle size of the nanoparticles can be an average value of maximum diameters of 100 particles measured through a transmission electron microscope, for example.

The dispersive medium of the dispersion of the electroconductive nanoparticles is not particularly limited, and can be appropriately selected in accordance with volatility, polarity, or wettability to the peelable substrate. Illustrative examples thereof include water, methanol, ethanol, 1-propanol, isopropyl alcohol, 1-butanol, acetone, methyl ethyl ketone, methyl isobutyl ketone, tetrahydrofuran, acetonitrile, N,N-dimethylformamide, N,N-dimethylacetamide, dimethyl sulfoxide, methylene chloride, chloroform, ethyl acetate, diethyl ether, dibutyl ether, benzene, toluene, xylene, hexane, formic acid, and acetic acid. They may be used alone or in combination of two or more kinds. The dispersion of electroconductive nanoparticles preferably has a nanoparticle concentration of 0.001 mass % or more and 30 mass % or less, more preferably 0.001 mass % or more and 10 mass % or less, still more preferably 0.001 mass % or more and 1 mass % or less.

The dispersion of electroconductive nanoparticles may further contain a resin component. Illustrative examples of the resin component include a polyester resin, a polyethylene resin, a cellulose resin, an acrylic resin, a styrene resin, a polyamide resin, a melamine resin, a phenol resin, an epoxy resin, and a silicone resin. They may be used alone or in combination of two or more kinds.

When the dispersion of electroconductive nanoparticles contains a resin, the viscosity is not particularly limited, but is preferably 1,000 mPa·s or less, more preferably 500 mPa·s or less, still more preferably 100 mPa·s or less in order to apply it through a nozzle by electrostatic force. Incidentally, the viscosity in this description refers to a value measured at 25° C. with a rotational viscometer by the method described in JIS K 7117-1:1999.

### [Application]

An apparatus used for applying the dispersion of electroconductive nanoparticles is the one that applies the dispersion of electroconductive nanoparticles by electrostatic force. The dispersion of electroconductive nanoparticles is applied by being sucked through a nozzle and applying voltage to the dispersion of electroconductive nanoparticles. The usable apparatuses are exemplified in JP 2009-016490A and JP 2014-120490A.

The shape of the nozzle is not particularly limited, but is preferably a circular shape in order to apply voltage uniformly to the dispersion of electroconductive nanoparticles.

The diameter of the nozzle is not particularly limited, but is preferably 1 μm or more and 100 μm or less, more preferably 1 μm or more and 80 μm or less, still more preferably 1 μm or more and 50 μm or less in order to form bumps with an average diameter of 1 μm or more and less than 100 μm. In this range, it is easy to apply bumps with an average diameter of 1 μm or more and less than 100 μm.

The voltage applied thereto is not particularly limited, but is preferably 1,000 V or more and 10,000 V or less, more preferably 1,000 V or more and 8,000 V or less, still more preferably 1,000 V or more and 5,000 V or less. The distance between the tip of the nozzle and the peelable substrate is, for example, 10 μm or more and 3,000 μm or less, preferably 10 μm or more and 2,000 μm or less.

### [Bump]

The average diameter of the bumps is 1 μm or more and less than 100 μm, more preferably 1 μm or more and 50 μm or less. The bumps are disposed at intervals of 1 μm or more and 100 μm or less, more preferably 1 μm or more and 50 μm or less. Incidentally, the average diameter of the bumps in the present invention may be an average value of maximum diameters of 100 bumps measured through Semiconductor & Flat Panel Display Inspection Microscope MX61 (manufactured by OLYMPUS CORPORATION).

### [Step (2)]

The step (2) is a step of coating a composition containing an insulating resin so as to have a thickness of 10 μm or more and 100 μm or less to coat surfaces of the bumps, whereby forming an insulating resin layer.

### [Composition Containing Insulating Resin]

The insulating resin is not particularly limited, and a thermosetting resin or a photo-setting resin is preferable. Illustrative examples thereof include a silicone resin, an epoxy resin, an acrylic resin, a polyester resin, a polyethylene resin, a cellulose resin, a styrene resin, a polyamide resin, a melamine resin, and a phenol resin. In view of the heat resistance and light resistance, a silicone resin and an epoxy resin are preferable, and a silicone resin is more preferable. The composition containing an insulating resin can contain any component other than the insulating resin, for example, solvent.

### [Insulating Resin Layer]

The insulating resin layer can be formed by a previously known method, and a film coater or a hot press machine can be used, for example. Illustrative examples of the film coater include a direct gravure coater, a chamber doctor coater, an offset gravure coater, a roll kiss coater, a reverse kiss coater, a bar coater, a die coater, a reverse roll coater, a slot die, an air doctor coater, a normal rotation roll coater, a blade coater, a knife coater, an impregnation coater, an MB coater, and an MB reverse coater. The coating may be performed by spraying through a nozzle using the same apparatus as the ones for applying the electroconductive nanoparticles.

The insulating resin layer has a thickness of 10 μm or more and 100 μm or less, more preferably 10 μm or more and 50 μm or less. In this range, electrical connection is successfully formed without having slippage of the electroconductive nanoparticles when a circuit electrode is pressed. In relation to the thickness of the insulating resin layer, the bumps preferably have diameters that are 10% or more and 90% or less, more preferably 10% or more and 70% or less of the thickness of the insulating resin layer. In this range, the electroconductive nanoparticles are allowed to connect to a circuit electrode more securely.

### [Step (3)]

The step (3) is a step of curing the insulating resin layer, followed by peeling the peelable substrate to obtain a film.

The curing method of the insulating resin layer is varied in accordance with the kind of resin and is not particularly limited. Illustrative examples thereof include heat-curing, photo-curing, and moisture-curing.

After curing the insulating resin layer, a peelable film may be bonded onto the insulating resin layer. Illustrative examples of the peelable film include PET films coated with a fluorine resin, PET films coated with a silicone resin, and fluorine resin films.

As described above, the inventive method for manufacturing an anisotropic conductive film makes it possible to manufacture an anisotropic conductive film in which bumps with an average diameter of 1 μm or more and less than 100 μm containing electroconductive nanoparticles are disposed at intervals of 1 μm or more and 100 μm or less.

### EXAMPLES

Hereinafter, the present invention will be specifically described by showing Synthesis Examples, Examples, and Comparative Examples, but the present invention is not limited to the following Examples.

In the following examples, weight average molecular weights are measured by gel permeation chromatography (GPC) in terms of polystyrene under the following conditions. In the following Synthesis Examples, Me represents a methyl group, Ph represents a phenyl group, and Vi represents a vinyl group.

### [Measurement Conditions]

Developing solvent: tetrahydrofuran (THF)
Flow amount: 0.6 mL/min
Detector: Differential refractive index detector (RI)
Column: TSK Guard column Super H-L
TSK gel Super H4000 (6.0 mm I.D.×15 cm×1)
TSK gel Super H3000 (6.0 mm I.D.×15 cm×1)
TSK gel Super H2000 (6.0 mm I.D.×15 cm×2)
(All of them manufactured by Tosoh Corporation) Column temperature: 40° C.
Sample injection amount: 20 μL (a THF solution with a concentration of 0.5 mass %)

### Synthesis Example 1

### Synthesis of Alkenyl Group-Containing Organopolysiloxane

Into a toluene solvent, 1142.1 g (87.1 mol %) of phenyltrichlorosilane, 529 g (3.2 mol %) of ClMe₂SiO(Me₂SiO)₃₃SiMe₂Cl, and 72.4 g (9.7 mol %) of dimethylvinylchlorosilane were dissolved. Subsequently, this was added dropwise to water to be subjected to co-hydrolysis, followed by washing with water, neutralization by washing with alkali, and dehydration. Then, the solvent was stripped to give phenyl group-containing vinylsilicone resin A1, which was solid at 25° C. The weight average molecular weight was 63,000.

### Synthesis Example 2

### Synthesis of Organohydrogenpolysiloxane

Into a toluene solvent, 1142.1 g (87.1 mol %) of phenyltrichlorosilane, 529 g (3.2 mol %) of ClMe₂SiO(Me₂SiO)₃₃SiMe₂Cl, and 69 g (9.7 mol %) of methyldichlorosilane were dissolved. Subsequently, this was added dropwise to water to be subjected to co-hydrolysis, followed by washing with water, neutralization by washing with alkali, and dehydration. Then, the solvent was stripped to give phenyl group-containing hydrogensilicone resin B1, which was solid at 25° C. The weight average molecular weight was 58,000.

Hereinafter, Examples 1 to 5 and Comparative Examples 1 to 4 will be described.

### Preparation of Dispersion of Electroconductive Nanoparticles

### Preparation Example 1

A dispersion of silver nanoparticles (23 mass %, viscosity: 200 mPa·s) was obtained by mixing 10 g of silver nanoink (manufactured by Sigma-Aldrich Co., LLC, concentration: 30 mass %, median diameter: 70 nm), 1 g of vinylsilicone resin A1 synthesized in Synthesis Example 1, 1 g of hydrogensilicone resin B1 synthesized in Synthesis Example 2, 2 mg of platinum (0)-1,3-divinyltetramethyldisiloxane complex (platinum concentration: 1 mass %), 6 mg of ethynylcyclohexanol, and 1 g of toluene.

### Preparation Example 2

A dispersion of silver nanoparticles (42 mass %, viscosity: 600 mPa·s) was obtained by mixing 10 g of a dispersion of silver nanoparticles NAG-25T (manufactured by DAIKEN CHEMICAL CO., LTD., concentration: 50 mass %, median diameter: 30 nm), 1 g of vinylsilicone resin A1 synthesized in Synthesis Example 1, 1 g of hydrogensilicone resin B1 synthesized in Synthesis Example 2, 2 mg of platinum (0)-1,3-divinyltetramethyldisiloxane complex (platinum concentration: 1 mass %), and 6 mg of ethynylcyclohexanol.

### Preparation Example 3

A dispersion of silver nanoparticles (80 mass %, viscosity: 2,000 mPa·s) was obtained by vacuum concentration of 10 g of an aqueous dispersion of silver nanoparticles NAG-28 (manufactured by DAIKEN CHEMICAL CO., LTD., concentration: 25 mass %, median diameter: 30 nm).

### Preparation Example 4

A dispersion of silver nanoparticles (1 mass %, viscosity: 3 mPa·s) was obtained by adding 240 g of terpineol to 10 g of an aqueous dispersion of silver nanoparticles NAG-28 (manufactured by DAIKEN CHEMICAL CO., LTD., concentration: 25 mass %, median diameter: 30 nm).

### Comparative Preparation Example 1

A silver nanoparticle paste (29 mass %) was obtained by mixing 10 g of vinylsilicone resin A1 synthesized in Synthesis Example 1, 10 g of hydrogensilicone resin B1 synthesized in Synthesis Example 2, 0.02 g of platinum (0)-1,3-divinyltetramethyldisiloxane complex (platinum concentration: 1 mass %), 0.06 g of ethynylcyclohexanol, 5 g of toluene, and 10 g of silver nanoparticles (manufactured by AS ONE Corporation, median diameter: 30 nm).

### Comparative Preparation Example 2

A silver nanoparticle paste (71 mass %) was obtained by mixing 10 g of vinylsilicone resin A1 synthesized in Synthesis Example 1, 10 g of hydrogensilicone resin B1 synthesized in Synthesis Example 2, 0.02 g of platinum (0)-1,3-divinyltetramethyldisiloxane complex (platinum concentration: 1 mass %), 0.06 g of ethynylcyclohexanol, and 50 g of silver nanoparticles (manufactured by AS ONE Corporation, median diameter: 30 nm).

### Manufacture of Anisotropic Conductive Film

### Example 1

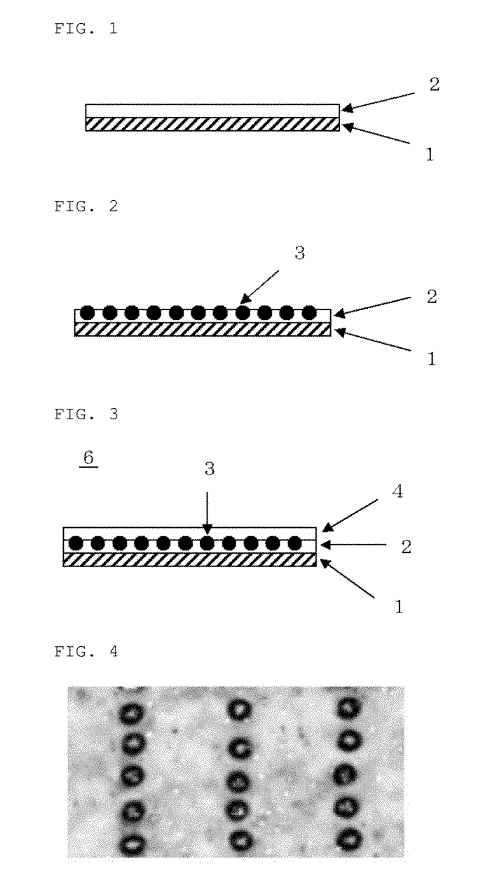

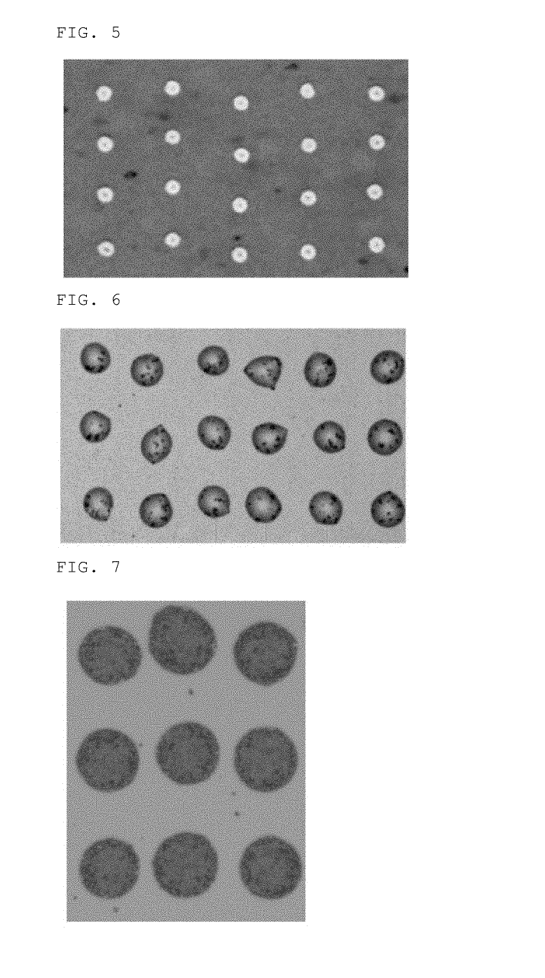

Organopolysiloxane composition 1 was prepared by mixing 100 g of vinylsilicone resin A1 synthesized in Synthesis Example 1, 100 g of hydrogensilicone resin B1 synthesized in Synthesis Example 2, 0.2 g of platinum (0)-1,3-divinyltetramethyldisiloxane complex (platinum concentration: 1 mass %), 0.6 g of ethynylcyclohexanol, and 50 g of toluene. Organopolysiloxane composition 1 was applied onto an ethylene-tetrafluoroethylene (ETFE) film (peelable substrate 1) using an auto film applicator PI-1210 (manufactured by TESTER SANGYO CO., LTD.) as shown in FIG. 1 to form a film having a length of 150 mm, a width of 150 mm, and a thickness of 15 μm. Then, this was heated at 100° C. for 30 minutes to evaporate toluene to form a base layer 2 having a length of 150 mm, a width of 150 mm, and a thickness of 10 μm, being solid at 25° C. with glass transition temperature of 40° C. Subsequently, the dispersion of silver nanoparticles produced in Preparation Example 1 was applied onto the base layer 2 using an electrostatic atomization/dispending experimental equipment (manufactured by APIC YAMADA CORPORATION) (nozzle diameter: 25 μm, applied voltage: 2,000 V, the distance to the base layer: 20 μm) (see FIG. 2). The bumps 3 of silver nanoparticle assemblies had an average diameter of 20 μm and an average interval of 40 μm (see FIG. 4). Then, the same Organopolysiloxane composition 1 as the base layer 2 was applied as a coating layer 4 for the bumps as in FIG. 3 using an auto film applicator PI-1210. This was heated to evaporate toluene to form a coating layer 4 having a length of 150 mm, a width of 150 mm, and a thickness of 30 μm, and an anisotropic conductive film 6 was obtained thereby.

### Example 2

A base layer 2 with a thickness of 5 μm was produced by the same way as in Example 1, and the dispersion of silver nanoparticles produced in Preparation Example 2 was applied onto the base layer 2 using an electrostatic atomization/dispending experimental equipment (nozzle diameter: 15 μm, applied voltage: 4,000 V, the distance to the base layer: 100 μm). The bumps 3 had an average diameter of 10 μm and an average interval of 30 μm (see FIG. 5). Then, a coating layer 4 having a length of 150 mm, a width of 150 mm, and a thickness of 30 μm was formed by the same method as in Example 1 to give an anisotropic conductive film 6.

### Example 3

A base layer 2 with a thickness of 25 μm was produced by the same way as in Example 1, and the dispersion of silver nanoparticles produced in Preparation Example 3 was applied onto the base layer 2 using an electrostatic atomization/dispending experimental equipment (nozzle diameter: 40 μm, applied voltage: 5,000 V, the distance to the base layer: 100 μm). The bumps 3 had an average diameter of 30 μm and an average interval of 30 μm (see FIG. 6). Then, a coating layer 4 having a length of 150 mm, a width of 150 mm, and a thickness of 50 μm was formed by the same method as in Example 1 to give an anisotropic conductive film 6.

### Example 4

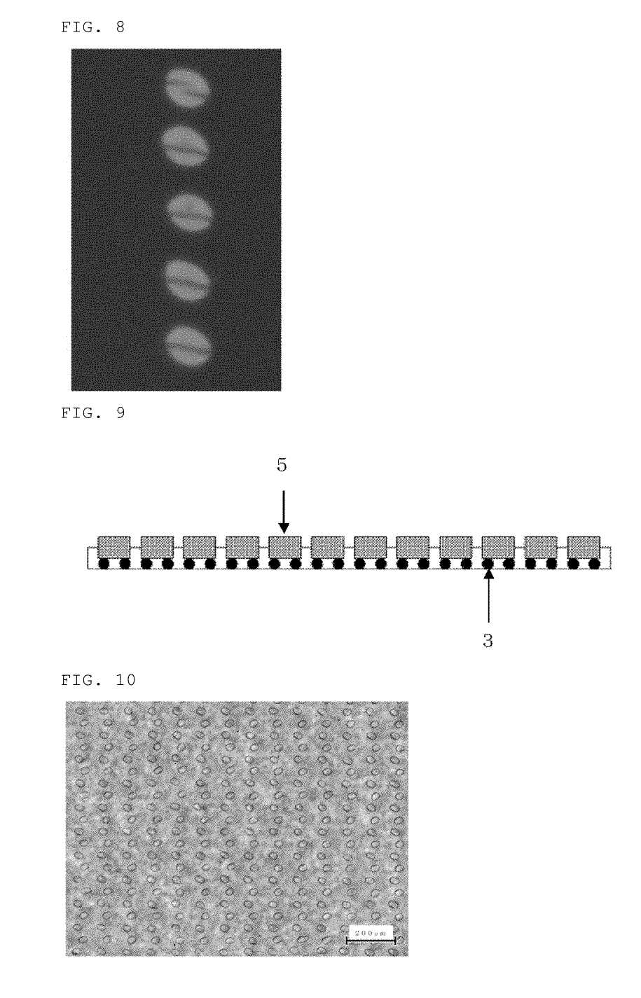

A base layer 2 with a thickness of 20 μm and glass transition temperature of 100° C. was produced by the same way as in Example 1 except for using an epoxy resin HB-EP100CL (manufactured by HUCKLEBORN) as the base layer 2, and the dispersion of silver nanoparticles produced in Preparation Example 3 was applied onto the base layer 2 using an electrostatic atomization/dispending experimental equipment (nozzle diameter: 70 μm, applied voltage: 3,000 V, the distance to the base layer: 200 μm). The bumps 3 had an average diameter of 100 μm and an average interval of 90 μm (see FIG. 7). Then, a coating layer 4 having a length of 150 mm, a width of 150 mm, and a thickness of 150 μm was formed by the same method as in Example 1 except for using HB-EP100CL as the coating layer 4 to give an anisotropic conductive film 6.

### Example 5

A base layer 2 with a thickness of 3 μm and glass transition temperature of 270° C. was produced by the same way as in Example 1 except for using a polyimide resin UPIA-AT (manufactured by UBE INDUSTRIES, LTD.) as the base layer 2, and the dispersion of silver nanoparticles produced in Preparation Example 4 was applied onto the base layer 2 using an electrostatic atomization/dispending experimental equipment (nozzle diameter: 10 μm, applied voltage: 5,000 V, the distance to the base layer: 10 μm). The bumps 3 had an average diameter of 4 μm and an average interval of 3 μm (see FIG. 8). Then, a coating layer 4 having a length of 150 mm, a width of 150 mm, and a thickness of 10 μm was formed by the same method as in Example 1 except for using UPIA-AT as the coating layer 4 to give an anisotropic conductive film 6.

### Comparative Example 1

The silver nanoparticle paste produced in Comparative Preparation Example 1 was applied onto an ETFE film using an auto film applicator PI-1210 to form a film having a length of 150 mm, a width of 150 mm, and a thickness of 30 μm. Then, this was heated at 100° C. for 30 minutes to evaporate toluene to form an anisotropic conductive film having a length of 150 mm, a width of 150 mm, and a thickness of 25 μm.

### Comparative Example 2

A metal mold having a lattice-form disposition pattern with a thickness of 50 μm was produced, with the intervals between the adjacent dispositions having width and narrowness. Into the metal mold, melted pellets of conventional transparent resin was poured and solidified by cooling to form a resin mold having a lattice-form disposition pattern, with the concave portions having width and narrowness. The concave portions of this resin mold was charged with the silver nanoparticle paste produced in Comparative Preparation Example 2. This was covered with an ETFE film and formed into a film having a length of 150 mm, a width of 150 mm, and a thickness of 50 μm to give an anisotropic conductive film.

### Comparative Example 3

A base layer with a thickness of 20 μm was produced by the same way as in Example 1, and the dispersion of silver nanoparticles produced in Preparation Example 3 was applied onto the base layer using an electrostatic atomization/dispending experimental equipment (nozzle diameter: 70 μm, applied voltage: 5,000 V, the distance to the base layer: 500 μm). The bumps had an average diameter of 100 μm and an average interval of 200 μm. Then, a coating layer having a length of 150 mm, a width of 150 mm, and a thickness of 150 μm was formed by the same method as in Example 1 to give an anisotropic conductive film.

### Comparative Example 4

A base layer with a thickness of 500 nm was produced by the same way as in Example 1, and the dispersion of silver nanoparticles produced in Preparation Example 4 was applied onto the base layer using an electrostatic atomization/dispending experimental equipment (nozzle diameter: 3 μm, applied voltage: 5,000 V, the distance to the base layer: 1 μm). The bumps had an average diameter of 1 μm and an average interval of 700 nm. Then, a coating layer having a length of 150 mm, a width of 150 mm, and a thickness of 1 μm was formed by the same method as in Example 1 to give an anisotropic conductive film.

### Measurement of Average Diameter of Bumps

Each average diameter of the bumps disposed on the base layer was measured through Semiconductor & Flat Panel Display Inspection Microscope MX61 (manufactured by OLYMPUS CORPORATION). The results are shown in Table 1.

### Measurement of Average Interval of Bumps

Each average interval of the bumps disposed on the base layer was measured through Semiconductor & Flat Panel Display Inspection Microscope MX61 (manufactured by OLYMPUS CORPORATION). The results are shown in Table 1.

### Energization Test

In each of the films obtained in Examples 1 to 5 and Comparative examples 1 to 4, the peelable substrate was peeled from the film. Onto the remained film, micro LEDs each having a size of 50 μm×50 μm and a thickness of 20 μm were pressed using a pick and place apparatus to be in a form having micro LEDs 5 pressed to the film as shown in FIG. 9 of a schematic view of the cross section of the film. Then, this was diced into pieces and mounted on a substrate. This was energized to measure the number of pieces that were lit up. The results are shown in Table 1.

TABLE 1

| | Example | Example | Example | Example | Example |
|---|---|---|---|---|---|
| | 1 | 2 | 3 | 4 | 5 |
| Features of | Base | Base | Base | Base | Base |
| film | layer + | layer + | layer + | layer + | layer + |
| | Particle | Particle | Particle | Particle | Particle |
| | assem- | assem- | assem- | assem- | assem- |
| | bly + | bly + | bly + | bly + | bly + |
| | Coating | Coating | Coating | Coating | Coating |
| | layer | layer | layer | layer | layer |
| Average | 20 | 10 | 30 | 100 | 4 |
| diameter of | | | | | |
| bumps (μm) | | | | | |
| Average | 40 | 30 | 30 | 90 | 3 |
| interval of | | | | | |
| bumps (μm) | | | | | |
| Energization | 20/20 | 20/20 | 20/20 | 20/20 | 20/20 |
| test (number | | | | | |
| of lighting) | | | | | |

| | Comparative | Comparative | Comparative | Comparative |
|---|---|---|---|---|
| | Example 1 | Example 2 | Example 3 | Example 4 |
| Features of | Film | Lattice | Base | Base |
| film | con- | form + | layer + | layer + |
| | taining | Film | Particle | Particle |
| | silver | con- | assem- | assem- |
| | paste | taining | bly + | bly + |
| | | silver | Coating | Coating |
| | | paste | layer | layer |
| Average | Unable | Unable | 100 | 1 |
| diameter of | to | to | | |
| bumps (μm) | measure | measure | | |
| Average | Unable | Unable | 200 | 0.7 |
| interval of | to | to | | |
| bumps (μm) | measure | measure | | |
| Energization | 0/20 | 5/20 | 0/20 | 2/20 |
| test (number | | | | |
| of lighting) | | | | |

As shown in Table 1, the inventive anisotropic conductive film successfully secured electric conduction without causing a short circuit even to semiconductor devices having fine electrodes such as micro LED unlike conventional anisotropic conductive films.

On the other hand, in Comparative Example 1 and Comparative Example 2, without using the inventive anisotropic conductive film, electric conduction could not be secured. In Comparative Example 3, electric conduction could not be secured since the average interval of the bumps was too long. In Comparative Example 4, the bumps, having a too short average interval, came to be in contact with both of the anode and the cathode of micro LED to cause a short circuit.

Hereinafter, Examples 6 to 9 and Comparative Examples 5 to 9 will be described.

### Production of Bumps Containing Electroconductive Nanoparticles

### Preparation Example 5

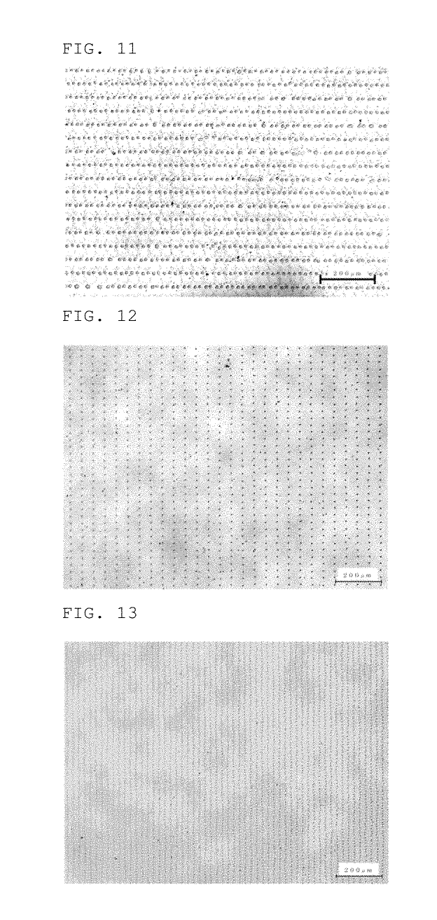

Onto an ETFE film, an aqueous dispersion of silver nanoparticles (manufactured by Sigma-Aldrich Co., LLC, concentration: 0.02 g/L, average particle size: 100 nm) was applied using an electrostatic atomization/dispending experimental equipment (manufactured by APIC YAMADA CORPORATION, nozzle diameter: 40 μm) with applied voltage of 4000 V and the distance from the film to the nozzle of 40 μm. The photograph of the appearance is shown in FIG. 10. The bumps had an average diameter of 27 μm and an average interval of 50 μm.

### Preparation Example 6

Onto an ETFE film, an aqueous dispersion of silver nanoparticles (manufactured by Sigma-Aldrich Co., LLC, concentration: 0.02 g/L, average particle size: 10 nm) was applied using an electrostatic atomization/dispending experimental equipment (manufactured by APIC YAMADA CORPORATION, nozzle diameter: 40 μm) with applied voltage of 3000 V and the distance from the film to the nozzle of 40 μm. The photograph of the appearance is shown in FIG. 11. The bumps had an average diameter of 14 μm and an average interval of 6 μm.

### Preparation Example 7

Onto an ETFE film, an aqueous dispersion of silver nanoparticles (manufactured by Sigma-Aldrich Co., LLC, concentration: 0.02 g/L, average particle size: 10 nm) was applied using an electrostatic atomization/dispending experimental equipment (manufactured by APIC YAMADA CORPORATION, nozzle diameter: 25 μm) with applied voltage of 2000 V and the distance from the film to the nozzle of 20 μm. The photograph of the appearance is shown in FIG. 12. The bumps had an average diameter of 4 μm and an average interval of 25 μm.

### Preparation Example 8

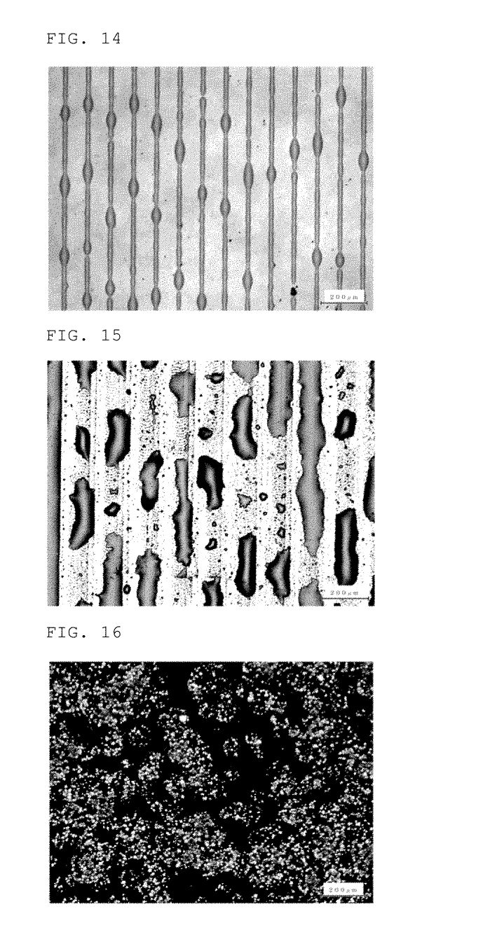

Onto an ETFE film, an aqueous dispersion of silver nanoparticles (manufactured by Sigma-Aldrich Co., LLC, concentration: 0.02 g/L, average particle size: 10 nm) was applied using an electrostatic atomization/dispending experimental equipment (manufactured by APIC YAMADA CORPORATION, nozzle diameter: 25 μm) with applied voltage of 1500 V and the distance from the film to the nozzle of 20 μm. The photograph of the appearance is shown in FIG. 13. The bumps had an average diameter of 4 μm and an average interval of 8 μm.

### Comparative Preparation Example 3

Onto an ETFE film, an aqueous dispersion of silver nanoparticles (manufactured by Sigma-Aldrich Co., LLC, concentration: 0.02 g/L, average particle size: 10 nm) was applied using a jet dispenser (manufactured by MUSASHI ENGINEERING, INC., nozzle diameter: 15 μm). As a result, the bumps were in contact with each other. The photograph of the appearance is shown in FIG. 14.

### Comparative Preparation Example 4

Onto an ETFE film, an aqueous dispersion of silver nanoparticles (manufactured by Sigma-Aldrich Co., LLC, concentration: 0.02 g/L, average particle size: 10 nm) was applied using an automatic air-less spray gun (manufactured by NORDSON CORPORATION, nozzle diameter: 50 μm). As a result, the bumps were in contact with each other. The photograph of the appearance is shown in FIG. 15.

### Comparative Preparation Example 5

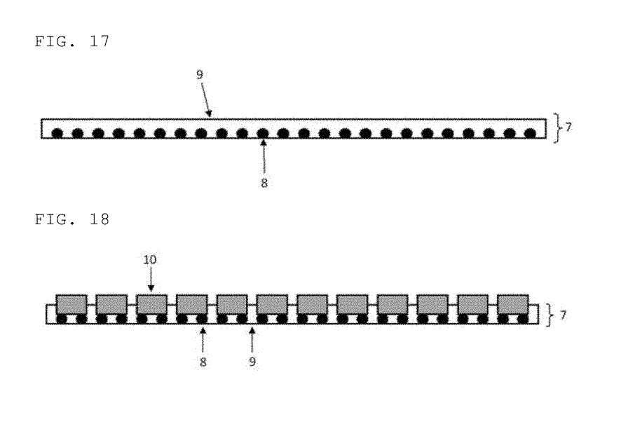

Onto an ETFE film, an aqueous dispersion of silver nanoparticles (manufactured by Sigma-Aldrich Co., LLC, concentration: 0.02 g/L, average particle size: 10 nm) was applied using a hand spray gun (nozzle diameter: 1 mm). As a result, the bumps had an average diameter of 2 μm, but was not disposed uniformly. The photograph of the appearance is shown in FIG. 16.

### Manufacture of Anisotropic Conductive Film

### Example 6

Organopolysiloxane composition 1 was prepared by mixing 100 g of vinylsilicone resin A1 synthesized in Synthesis Example 1, 100 g of hydrogensilicone resin B1 synthesized in Synthesis Example 2, 0.2 g of platinum (0)-1,3-divinyltetramethyldisiloxane complex (platinum concentration: 1 mass %), 0.6 g of ethynylcyclohexanol, and 50 g of toluene. Using an auto film applicator PI-1210 (manufactured by TESTER SANGYO CO., LTD.), Organopolysiloxane composition 1 was applied onto the ETFE film on which silver bumps had been applied produced in Preparation Example 5 to form a film having a length of 150 mm, a width of 150 mm, and a thickness of 60 μm. Then, this was heated at 100° C. for 30 minutes to evaporate toluene. Subsequently, the ETFE film was peeled therefrom to give a film having a length of 150 mm, a width of 150 mm, and a thickness of 50 μm, being solid at 25° C. with glass transition temperature of 40° C. Regarding thus obtained film, the schematic view of the cross section is shown in FIG. 17. The film 7 is composed of bumps 8 and the insulating resin layer 9.

### Example 7

A film having a length of 150 mm, a width of 150 mm, and a thickness of 50 μm was obtained by the same way as in Example 6 except for using the ETFE film on which bumps had been formed produced in Preparation Example 6.

### Example 8

Using the ETFE film on which bumps had been formed produced in Preparation Example 7, Organopolysiloxane composition 1 was applied by the same way as in Example 6 to form a film having a length of 150 mm, a width of 150 mm, and a thickness of 25 μm. Then, this was heated at 100° C. for 30 minutes to evaporate toluene. Subsequently, the ETFE film was peeled therefrom to give a film having a length of 150 mm, a width of 150 mm, and a thickness of 20 μm.

### Example 9

A film having a length of 150 mm, a width of 150 mm, and a thickness of 20 μm was obtained by the same way as in Example 8 except for using the ETFE film on which bumps had been formed produced in Preparation Example 8.

### Comparative Example 5

A film having a length of 150 mm, a width of 150 mm, and a thickness of 50 μm was obtained by the same way as in Example 6 except for using the ETFE film on which an aqueous dispersion of silver nanoparticles had been applied produced in Comparative Preparation Example 3.

### Comparative Example 6

A film having a length of 150 mm, a width of 150 mm, and a thickness of 50 μm was obtained by the same way as in Example 6 except for using the ETFE film on which an aqueous dispersion of silver nanoparticles had been applied produced in Comparative Preparation Example 4.

### Comparative Example 7

A film having a length of 150 mm, a width of 150 mm, and a thickness of 50 μm was obtained by the same way as in Example 6 except for using the ETFE film on which an aqueous dispersion of silver nanoparticles had been applied produced in Comparative Preparation Example 5.

### Comparative Example 8

Organopolysiloxane composition 1′ was prepared by mixing 100 g of vinylsilicone resin A1 synthesized in Synthesis Example 1, 100 g of hydrogensilicone resin B1 synthesized in Synthesis Example 2, 0.2 g of platinum (0)-1,3-divinyltetramethyldisiloxane complex (platinum concentration: 1 mass %), 0.6 g of ethynylcyclohexanol, 50 g of toluene, and 10 g of silver nanoparticles (manufactured by AS ONE Corporation, median diameter: 30 nm). Organopolysiloxane composition 1′ was applied onto an ETFE film using an auto film applicator PI-1210 (manufactured by TESTER SANGYO CO., LTD.) to form a film having a length of 150 mm, a width of 150 mm, and a thickness of 60 μm. Then, this was heated at 100° C. for 30 minutes to evaporate toluene. Subsequently, the ETFE film was peeled therefrom to give a film having a length of 150 mm, a width of 150 mm, and a thickness of 50 μm, being solid at 25° C. with glass transition temperature of 45° C.

### Comparative Example 9

A metal mold having a lattice-form disposition pattern with a thickness of 50 μm was produced, with the intervals between the adjacent dispositions having width and narrowness. Into the metal mold, melted pellets of conventional transparent resin was poured and solidified by cooling to form a resin mold having a lattice-form disposition pattern, with the concave portions having width and narrowness. The concave portions of this resin mold was charged with Organopolysiloxane composition 1′ containing electroconductive particles produced in Comparative Example 8. This was covered with an ETFE film and formed into a film having a length of 150 mm, a width of 150 mm, and a thickness of 60 μm. Then, this was heated at 100° C. for 30 minutes to evaporate toluene. Subsequently, the ETFE film was peeled therefrom to give a film having a length of 150 mm, a width of 150 mm, and a thickness of 50 μm.

### Measurement of Average Diameter of Bumps

Each average diameter of the bumps disposed on the ETFE film was measured through Semiconductor & Flat Panel Display Inspection Microscope MX61 (manufactured by OLYMPUS CORPORATION). The results are shown in Table 2.

### Measurement of Average Interval of Bumps

Each average interval of the bumps disposed on the ETFE film was measured through Semiconductor & Flat Panel Display Inspection Microscope MX61 (manufactured by OLYMPUS CORPORATION). The results are shown in Table 2.

### Energization Test

Onto each of the films obtained in Examples 6 to 9 and Comparative examples 5 to 9, micro LEDs each having a size of 50 μm×50 μm and a thickness of 20 μm were pressed using a pick and place apparatus to be in a form having micro LEDs 10 pressed to the film 7 as shown in FIG. 18 of a schematic view of the cross section of the film. Then, this was diced into pieces, mounted on a substrate, and subjected to lighting test. This was evaluated as Good when it lighted, and as Bad when it did not light. The results are shown in Table 2.

TABLE 2

| | Example 6 | Example 7 | Example 8 | Example 9 |
|---|---|---|---|---|
| Method for | Electro- | Electro- | Electro- | Electro- |
| disposing | static | static | static | static |
| electro- | atom- | atom- | atom- | atom- |
| conductive | ization/ | ization/ | ization/ | ization/ |
| particles | dispending | dispending | dispending | dispending |
| | experi- | experi- | experi- | experi- |
| | mental | mental | mental | mental |
| | equipment | equipment | equipment | equipment |
| Average | 27 | 14 | 4 | 4 |
| diameter of | | | | |
| bumps (μm) | | | | |
| Average | 50 | 6 | 25 | 8 |
| interval of | | | | |
| bumps (μm) | | | | |
| Energization | Good | Good | Good | Good |
| test | | | | |

| | Compara- | Compara- | Compara- | Compara- | Compara- |
|---|---|---|---|---|---|
| | tive | tive | tive | tive | tive |
| | Example | Example | Example | Example | Example |
| | 5 | 6 | 7 | 8 | 9 |
| Method for | Jet dis- | Automat- | Hand | Resin | Resin |
| disposing | penser | ic air- | spray | mixing | mixing |
| electro- | | less | gun | | |
| conductive | | spray | | | |
| particles | | gun | | | |
| Average | Unable | Unable | 2 | Unable | Unable |
| diameter of | to | to | | to | to |
| bumps (μm) | measure | measure | | measure | measure |
| Average | Unable | Unable | Unable | Unable | Unable |
| interval of | to | to | to | to | to |
| bumps (μm) | measure | measure | measure | measure | measure |
| Energization | Bad | Bad | Bad | Bad | Bad |
| test | | | | | |

As shown in Table 2, with each anisotropic conductive film in which electroconductive nanoparticles had been disposed regularly by electrostatic force according to the inventive manufacturing method, electric conduction was successfully secured without causing a short circuit even to semiconductor devices having fine electrodes such as micro LED unlike conventional anisotropic conductive films.

On the other hand, in Comparative Example 5 to Comparative Example 7, having failed to dispose the electroconductive nanoparticles regularly as in Examples, electric conduction could not be secured. In Comparative Examples 8 and 9, the electroconductive nanoparticles were aggregated to be in contact with both of the anode and the cathode of micro LED to cause a short circuit.

It is to be noted that the present invention is not restricted to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. An anisotropic conductive film comprising:
a peelable substrate,
a base layer containing an insulating resin on the peelable substrate,
bumps of electroconductive nanoparticle assemblies disposed on the base layer at intervals of 1 μm to 100 μm, and
a coating layer containing an insulating resin formed on the base layer so as to coat the bumps,
wherein the peelable substrate is peelable to the base layer.

2. The anisotropic conductive film according to claim 1, wherein the bumps have an average diameter of 1 μm to 100 μm.

3. The anisotropic conductive film according to claim 1, wherein the electroconductive nanoparticle assemblies are each an assembly composed of electroconductive nanoparticles having primary particle sizes of 1 nm to 500 nm.

4. The anisotropic conductive film according to claim 2, wherein the electroconductive nanoparticle assemblies are each an assembly composed of electroconductive nanoparticles having primary particle sizes of 1 nm to 500 nm.

5. The anisotropic conductive film according to claim 1, wherein the base layer has a thickness that is 1% to 100% of the average diameter of the bumps.

6. The anisotropic conductive film according to claim 2, wherein the base layer has a thickness that is 1% to 100% of the average diameter of the bumps.

7. The anisotropic conductive film according to claim 1, wherein the coating layer has a thickness that is 101% to 500% of the average diameter of the bumps.

8. The anisotropic conductive film according to claim 2, wherein the coating layer has a thickness that is 101% to 500% of the average diameter of the bumps.

9. The anisotropic conductive film according to claim 1, wherein at least either of the base layer and the coating layer contains a silicone resin as the insulating resin, containing the following components (A), (B), and (C):
(A) a silicone resin shown by the following average formula (1):
R¹ₐR²_{b}R³_{c}(OX)_{d}SiO_{(4-a-b-c-d)/2} (1)
wherein R¹ represents a monovalent aromatic hydrocarbon group having 6 to 12 carbon atoms; R² represents a saturated hydrocarbon group having 1 to 6 carbon atoms; R³ represents an alkenyl group having 2 to 6 carbon atoms; X represents a monovalent hydrocarbon group having 1 to 6 carbon atoms or a hydrogen atom; and “a”, “b”, “c”, and “d” are each number of a≥0, b>0, c>0, and d≥0, satisfying a+b+c+d=1 to 2; provided that at least two alkenyl groups are contained in one molecule;
(B) a silicone resin shown by the following average formula (2):
R¹ₑR²_{f}H_{g}(OX)ₕSiO_{(4-e-f-g-h)/2} (2)
wherein R¹, R², and X represent the same meanings as R¹, R², and X described above; “e”, “f”, “g”, and “h” are each number of e≥0, f>0, g>0, and h≥0, satisfying e+f+g+h=1 to 2; provided that at least two silicon atom-bonded hydrogen atoms are contained in one molecule; and
(C) a hydrosilylation catalyst.

10. The anisotropic conductive film according to claim 9, wherein the silicone resin is solid at 25° C.

11. A method for manufacturing an anisotropic conductive film, comprising the steps of:
(1) performing coating of a composition containing an insulating resin onto a peelable substrate to form a base layer;
(2) applying voltage to a dispersion of electroconductive nanoparticles to apply the dispersion of electroconductive nanoparticles onto the base layer through a nozzle by electrostatic force, whereby disposing bumps of electroconductive nanoparticle assemblies on the base layer at intervals of 1 μm to 100 μm; and
(3) performing coating of a composition containing an insulating resin so as to coat surfaces of the bumps to form a coating layer on the base layer.

12. The method for manufacturing an anisotropic conductive film according to claim 11, further comprising the steps of:
(1)′ curing the base layer between the step (1) and the step (2); and/or
(3)′ curing the coating layer after the step (3).

13. A method for manufacturing an anisotropic conductive film, comprising the steps of:
(1) applying voltage to a dispersion of electroconductive nanoparticles to apply the dispersion of electroconductive nanoparticles onto a peelable substrate through a nozzle by electrostatic force, whereby disposing bumps having an average diameter of 1 μm or more and less than 100 μm on the peelable substrate at intervals of 1 μm or more and 100 μm or less;
(2) performing coating of a composition containing an insulating resin so as to have a thickness of 10 μm or more and 100 μm or less to coat surfaces of the bumps, whereby forming an insulating resin layer; and
(3) curing the insulating resin layer, followed by peeling the peelable substrate to obtain a film.

14. The method for manufacturing an anisotropic conductive film according to claim 13, wherein the bumps have diameters that are 10% or more and 90% or less of the thickness of the film.

15. The method for manufacturing an anisotropic conductive film according to claim 13, wherein the insulating resin layer is cured by any of heat-curing, photo-curing, and moisture-curing.

16. The method for manufacturing an anisotropic conductive film according to claim 14, wherein the insulating resin layer is cured by any of heat-curing, photo-curing, and moisture-curing.

17. The method for manufacturing an anisotropic conductive film according to claim 13, wherein the dispersion of electroconductive nanoparticles has a nanoparticle concentration of 0.001 mass % or more and 30 mass % or less.

18. The method for manufacturing an anisotropic conductive film according to claim 14, wherein the dispersion of electroconductive nanoparticles has a nanoparticle concentration of 0.001 mass % or more and 30 mass % or less.

19. The method for manufacturing an anisotropic conductive film according to claim 13, wherein the insulating resin is a silicone resin.

20. The method for manufacturing an anisotropic conductive film according to claim 13, wherein the insulating resin is solid at 25° C.
